(19) United States
(12) Patent Application Publication
(10) Pub. No.: US 2008/0080133 A1
(43) Pub. Date: Apr. 3, 2008

(54) FLAT TYPE HEAT PIPE DEVICE AND METHOD OF FABRICATION THEREOF

(76) Inventors: Hsiu-Wei Yang, Kaohsiung (TW); Pei-Pei Ding, Kaohsiung (TW); Wen-Hwa Yu, Kaohsiung (TW); Chih-Hua Wu, Kaohsiung (TW); Tsao-Hsiang Cheng, Kaohsiung (TW)

Correspondence Address: G. LINK CO., LTD., 3550 BELL ROAD, MINOOKA, IL, 60447, US

(21) Appl. No.: 11/537,913

(22) Filed: Oct. 2, 2006

(51) Int. Cl. H05K 7/20

(52) U.S. Cl. 361/688

(57) ABSTRACT

A flat type heat pipe device includes a packaging unit and a bonding member. The packaging unit further includes a first shell member and a second shell member. The first shell member has a work zone, a first joining part surrounding the work zone and an upright stop part disposed between the work zone and the joining part. The second shell member provides a shape corresponding to the first shell member to cover the first shell member and has a shell lid part spacing apart from the work zone and a second joining part disposed on the first joining part. The bonding member is disposed between the first joining part and the second joining part to adhere the first joining part to the second joining part. When the first shell member is pressingly fit with second shell member, the stop part is capable of preventing the bonding member from entering the packaging unit.

### BACKGROUND OF THE INVENTION

1. Field of the Invention

The present invention is related to a heat pipe device particularly to a flat type heat pipe device with packaging unit and method for making the heat pipe device.

2. Brief Description of the Related Art

Referring to FIGS. 1 and 2, the conventional flat type heat pipe 1 includes a packaging unit 11, a soldering paste 13, a capillary device 12 and a work fluid 14.

The packaging unit 11 includes a first shell member 111 and a second shell member 112. The second shell member 112 has a shape corresponding to the first shell member 111. The first shell member 111 has a work zone 113 and a first joining part 114 surrounding the work zone 113. The first joining part 114 has a first channel 115 extending from the periphery thereof to the work zone 113 and has a filling pipe 116 received in the first channel 115.

The second shell member 112, which covers the first shell member 111, has shell lid part 117 spacing part from the work zone 113 and a second joining part 118 on the first joining part 114. The second joining part 118 further has a second channel 119 corresponding to the first channel 115 for accommodating the filling pipe 116.

The soldering paste 13 is disposed between the first joining part 114 and the second joining part 118 for adhering the joining parts 114, 118.

The capillary device 12 and the work fluid 14 are received in a chamber 110 defined by the first shell member 111 and the shell lid 117.

When the flat type heat pipe device is assembled, the soldering paste 13 with flux is coated on the first and second joining parts 114, 118 first, then, the capillary device 12 is placed between the work zone 113 and the shell lid part 117, and, next, a fixture (not shown) is employed to allow the first joining part 114 pressingly fitting with the second joining part 118 for the joining parts 114, 118 adhering to each other with the soldering paste 13. Further, the flat type heat pipe 1 is treated in a high temperature stove (not shown) and cooled down afterward for soldering paste 13 tightly joining the first and second shell members 111, 112. Finally, the work fluid 14 is filled in the chamber 110 via the filling pipe 116.

When the first shell member 111 is pressed to join the second shell member 112, part of the soldering paste 13 is squeezed into the chamber 110 easily to influence properties and functions of the capillary device 12 and the work fluid 14 so as to decrease capability of heat dissipation of the flat type heat pipe 1.

Furthermore, the flux in the soldering paste 13 acts to corrode oxidized layer (not shown) on the first and second joining parts 114, 118 and restrain tin solder itself from oxidization for performing eutectic reaction completely. The flux is strong acid with high fluidity such that it is much more easily to influence the properties and functions of the capillary device 12 and the work fluid 14. As a result, it worsens the capability of heat dissipation of the flat type heat pipe.

### SUMMARY OF THE INVENTION

In order to solve the preceding problems, an object of the present invention is to provide a flat type heat pipe device which is capable of providing more steady capability of heat dissipation.

Another object of the present invention is to provide a method for making a flat type heat pipe device which is capable of providing more steady capability of heat dissipation.

A further object of the present invention is to provide a flat type heat pipe device with which the bonding substance is incapable of entering the chamber to influence properties and functions of the capillary device and the work fluid for maintaining the capability of heat dissipation of the flat type heat pipe device and the packaging unit thereof.

A further object of the present invention is to provide a method for making and packaging a flat type heat pipe device with which the bonding substance is incapable of entering the chamber to influence properties and functions of the capillary device and the work fluid for maintaining the capability of heat dissipation of the flat type heat pipe device and the packaging unit thereof.

A further object of the present invention is to provide a flat type heat pipe device with which the two shell members are joined to each other tightly.

A further object of the present invention is to provide a method for making and packaging a flat type heat pipe device with which the two shell members are joined to each other tightly.

Accordingly, a flat type heat pipe device according to the present invention includes a packaging unit and a bonding member.

The packaging unit includes a first shell member and a second shell member. The first shell member has a work zone, a first joining part surrounding the work zone and an upright stop part disposed between the work zone and the joining part. The second shell member provides a shape corresponding to the first shell member to cover the first shell member and has a shell lid part spacing apart from the work zone and a second joining part disposed on the first joining part.

The bonding member is disposed between the first joining part and the second joining part to adhere the first joining part to the second joining part.

A method for making a flat type heat pipe device according to the present invention includes following steps:

(A) providing a first shell member and a second shell member, which have a shape corresponding to each other, the first shell member having a work zone, a first joining part surrounding the work zone and an upright stop part disposed between the work zone and the first joining part, and the second shell member having a shell lid part corresponding to the work zone and a second joining part corresponding to the first joining part;

(B) coating a bonding member on at least one of the first and second joining parts; and

(C) covering the first shell member with the second shell member to allow the second shell member being attached to the first shell member.

The feature of the present invention is in that an upright stop part is added between the work zone and the first joining part to limit an extent of the coated bonding member and prevent the bonding member from entering the chamber during the first shell member and the second shell member being pressingly joined to each other to secure properties and functions of the capillary device and the work fluid and maintain the capability of heat dissipation of the flat type heat pipe device.

### BRIEF DESCRIPTION OF THE DRAWINGS

The detail structure, the applied principle, the function and the effectiveness of the present invention can be more fully understood with reference to the following description and accompanying drawings, in which:

FIG. 1 is a disassembled perspective view of the conventional flat type heat pipe;

FIG. 2 is an assembled sectional view of the conventional flat type heat pipe shown in FIG. 1;

FIG. 3 is a disassembled perspective view of the first embodiment of a flat type heat pipe device according to the present invention;

FIG. 4 is an assembled sectional view of the flat type heat device of the first embodiment shown in FIG. 3;

FIG. 5 is a flow chart illustrating manufacturing process of the flat type heat pipe device of the first embodiment according to the present invention;

FIG. 6 is a sectional view of a flat type heat pipe device of the second embodiment according to the present invention;

FIG. 7 is a sectional view of a flat type heat pipe device of the third embodiment according to the present invention; and

FIG. 8 is a perspective view illustrating a fixture used in the manufacturing process to clamp a first and a second shell members, which are provided in the flat type heat pipe device of the first embodiment according to the present invention.

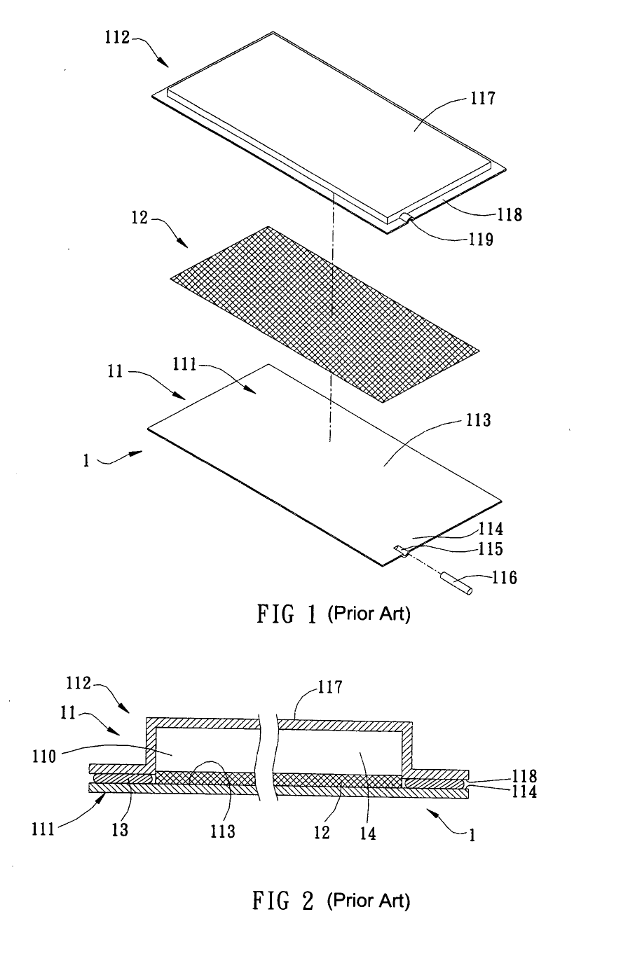

### DETAILED DESCRIPTION OF THE INVENTION

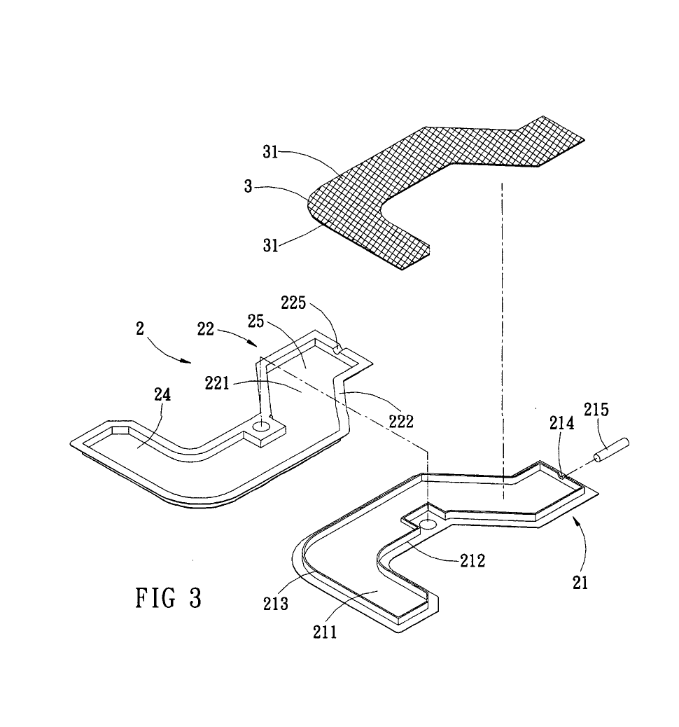

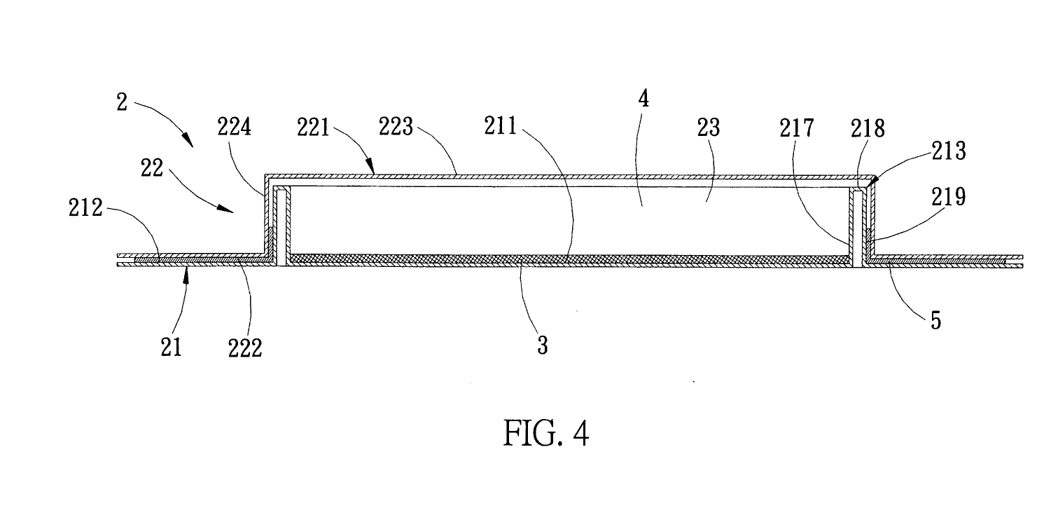

Referring to FIGS. 3 and 4, a flat type heat pipe device of the first embodiment according to the present invention includes a packaging unit 2, a bonding member 5, a capillary device 3 and a working fluid 4.

The packaging unit further includes a first shell member 21 and a second shell member 22, which is corresponding to and oppositely joined to the first shell member 21. The first and second shell members 21, 22 are made of one of aluminum and copper in the first embodiment. Alternatively, other material with good extensibility and heat conductivity is capable of being made as the shell members 21, 22 in addition to the aluminum or copper.

The first shell member 21 has a work zone 211, a first joint part 212 and a stop part 213. The first joint part 212 surrounds the work zone 211 and is disposed at the same elevation as the work zone 211. The stop part 213 is disposed between the work zone 211 and the first joint part 212 in a way of being upright from the first shell member 21.

The stop part 213 has a elongated channel shaped cross section with an inner vertical section 217, a top horizontal section 218 and an outer vertical section 219.

The first shell member 21 is a cast integral piece in the first embodiment. Alternatively, the stop part 213 can be plated in place or attached to the position between the work zone 211 and the first joint part 212 with any other working ways.

The first joint part 212 has a first groove 214 extending to the work zone 211 and a filling pipe section 215 is inserted into the first groove 214 and welded to the first joint part 212 with the outer end of the filling pipe 215 being a closed end (detail description afterward). The first joint part 212 is a flat shaped horizontal wall in the first embodiment. Alternatively, the first joint part 212 can be shapes different from the flat shaped horizontal wall in practice.

The bonding member 5 is disposed between the first joining part 212 and the second joining part 222 for adhering both of the joining parts 212, 222. The joining member 5 is a soldering paste with flux or soldering wires without flux. Alternatively, air-tight glue or adhesives can be used for joining the joining parts 212, 222. The flux is capable of corroding oxidized layer (not shown) on the joining parts 212, 222 and resisting tin solder from being oxidized for eutectic reaction being performed completely. In this way, air-tight joint between the first shell member 21 and the second shell member 22 can be secured.

As the foregoing, the soldering wires without flux can be employed and protective gas is introduced to protect the joining parts 212, 222 from being oxidized. For instance, the protective gas containing 95% nitrogen and 5% hydrogen can be used and the nitrogen acts as the protection gas and hydrogen performs reduction reaction with oxide layer on the joining parts 212, 222 to remove the oxide layer. Hence, the protective gas replaces function of the flux.

The capillary device 3 and the work fluid 4 is disposed in a chamber 23 defined by the work zone 211 of the first shell member 21 and the shell lid 221 of the second shell member 22. The capillary device 3 is a metal net in the work fluid 4 in the instant embodiment and includes a plurality of capillary apertures 31. Alternatively, the capillary device 3 can be formed with another other way such as providing a plurality of upright capillary tubes (not shown) or being integrally joined to the work zone 211 or the shell lid part 221.

The capillary device 3 is capable of resulting in capillary phenomenon of liquid so that once a portion of the capillary device 3 contacts with liquid, the liquid can diffuse to rest of the capillary device 3 and the diffusion is independent of direction of the gravity. Hence, sizes of the capillary apertures depend on what material of the capillary device 3 is and what the work fluid 4 is.

The work fluid 4 is water in the instant embodiment but another liquid such as methyl alcohol or propyl alcohol can be employed as the work fluid too.

The packaging unit 2 further includes a heat absorption end 24 and a heat releasing end 25. Pressure in the chamber 23 is equal to saturated vapor pressure of the work fluid 4 such that the work fluid 4 is in a steadily balancing state between liquid state and gaseous state.

When the heat absorption end 24 is heated to increase temperature thereof, the steady state of balance is unable to be kept and the work fluid 4 at the heat absorption end 24 vaporizes as gaseous work fluid 4. Under this circumstance, the vapor pressure at the heat absorption end 24 is greater than that at the heat releasing end and the gaseous work fluid 4 diffuses toward the heat releasing end 25. The heat releasing end 25 is lower in temperature so that the gaseous work fluid 4 is condensed as liquid work fluid 4 and excessive liquid work fluid 4 flows back to the heat absorption end 24. In this way, a heat guiding process for heat conducting to the heat releasing end 25 from the heat absorption end is complete.

The heat guiding process results from the steady state of balance being unable to be kept so that the heat guiding process performs heat conduction continuously if and only if temperature between the heat absorption end and the heat releasing end is different. Different work fluids 4 provide different work temperatures and it is incapable of performing the heat guiding process any more while the ambient temperature is higher than the work temperature.

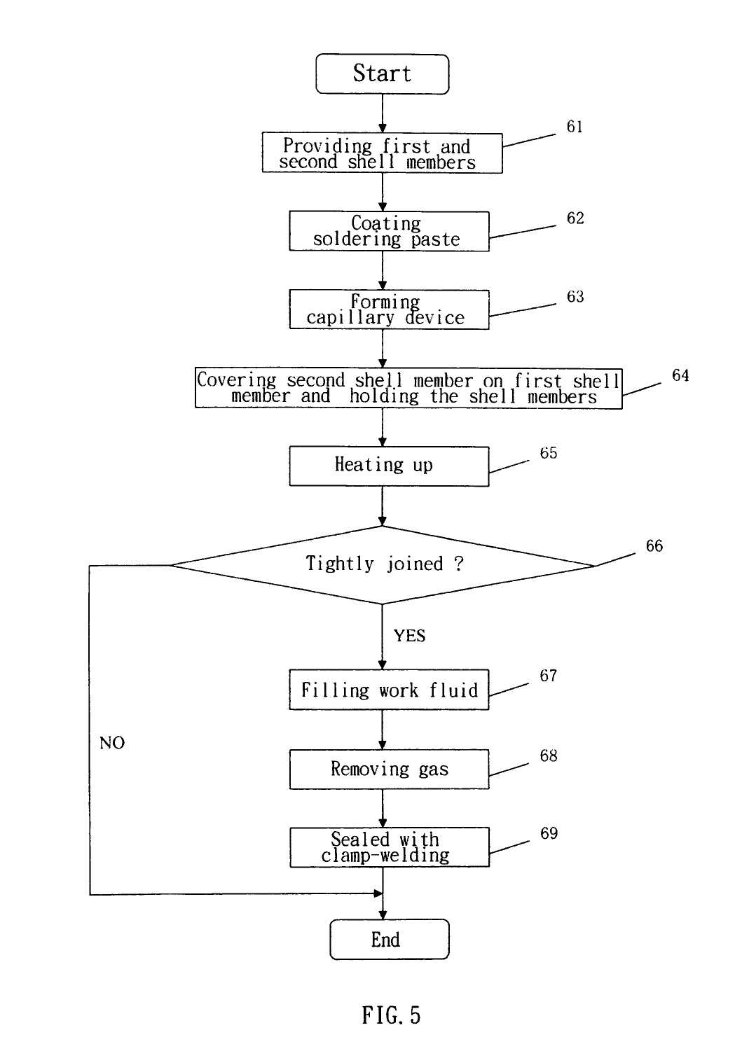

Referring to FIG. 5 in company with FIGS. 3 and 4, a method for making the flat type heat pipe of the instant embodiment according to the present invention is illustrated. Steps of the method are described hereinafter:

Step 61 is to provide the first shell member 21 and the second shell member 22 and the filling pipe 215 is placed in the first groove 214 of the first shell member 21. Because the filling pipe 215 provides a length greater than the first groove 214, an end of the filling pipe 215 passes through the stop part 213 to communicate with work zone 211 and another end of the filling pipe 215 extends outward the first shell member 21.

Step 62 is that the bonding member 5 is provided and coated on at least one of the first joining part 212 and the second joining part 222. The bonding member 5 is the soldering paste in the instant embodiment and the first and second joining part 212, 222 are coated with the soldering paste.

Step 63 is to provide a capillary device 3, which is formed at the work zone 211 of the first shell member 21. The capillary device 3 is a metal net in the instant embodiment. It is known by the skill persons of the art that step 62 and step 63 are interchangeable in sequence of the process and it is not limited with the instant embodiment.

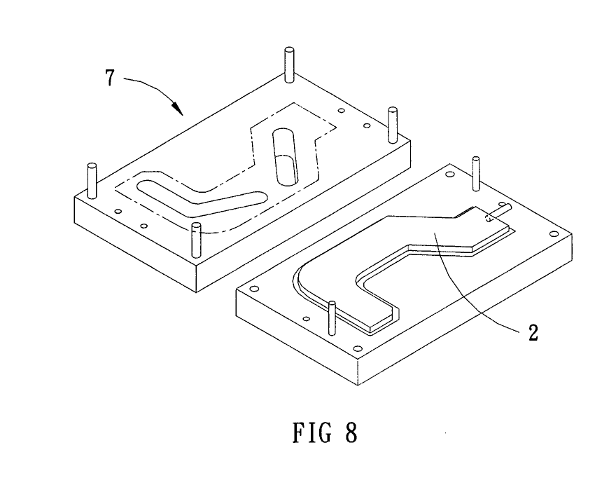

Step 64 is to cover the second shell member 22 on the first shell member 21 with a fixture 7 (shown in FIG. 8) holding the shell members 21, 22 in place firmly.

The bonding member 5 is the soldering paste in the instant embodiment so that step 65 is to move the joined first and second shell members 21, 22 in a high temperature stove (not shown) or to heat the joined first and second shell members 21, 22 with a hot air gun (not shown) for the bonding member 5 being melted and adhered to the first joining part 212 and the second joining part 222. The joining parts 212, 222 are cooled down and joined to each other with bonding member 5 after heating process. Once the joining parts 212, 222 are attached to each other, the chamber 23 can communicate with outside by means of the filling pipe 215. The high temperature stove is a back-soldering stove (not shown). In case of the no solder tin being contained in the bonding member 5, step 65 is skipped and step 66 is processed directly.

If the first joining part 212 is not joined to the second joining part 222 tightly, it means the chamber 23 can communicate with the outside via other spots in addition to the filling pipe 215 and the flat type heat pipe is unable to work normally. Hence, step 66 is to provide a leakage test to verify if the first joining part 212 is attached to the second joining part 222 tightly. If leakage is happened during the test, the manufacturing process for the flat type heat pipe of the instant embodiment is stopped completely to avoid infective flat type pipe. If no leakage is happened during the test, it means that the first joining part 21 is attached to the second joining part tightly and step 67 can be further processed.

Step 67 is to provide an air removable filling device (not shown) and the work fluid 4 is filled in the chamber 23 with the filling device.

Step 68 is to provide the air removable filling device again for reducing pressure in the chamber 23 and the filling pipe so as to suck out residue air in the chamber 23. In this way, the pressure in the chamber 23 can be adjusted to be equal to the saturated vapor pressure of the work fluid.

Step 69 is to provide a clamp-welding for the outer end of the filling pipe 215 being sealed. A clamping device (not shown) is employed to hold outer end of the filling pipe 215 and a shear device (not shown) is employed to cut off the filling pipe 215. Further, a seam welding device (not shown) is employed to spot-weld the filling pipe 215 to allow the filling pipe 215 being completely air-tight to finish fabrication of the flat type heat pipe.

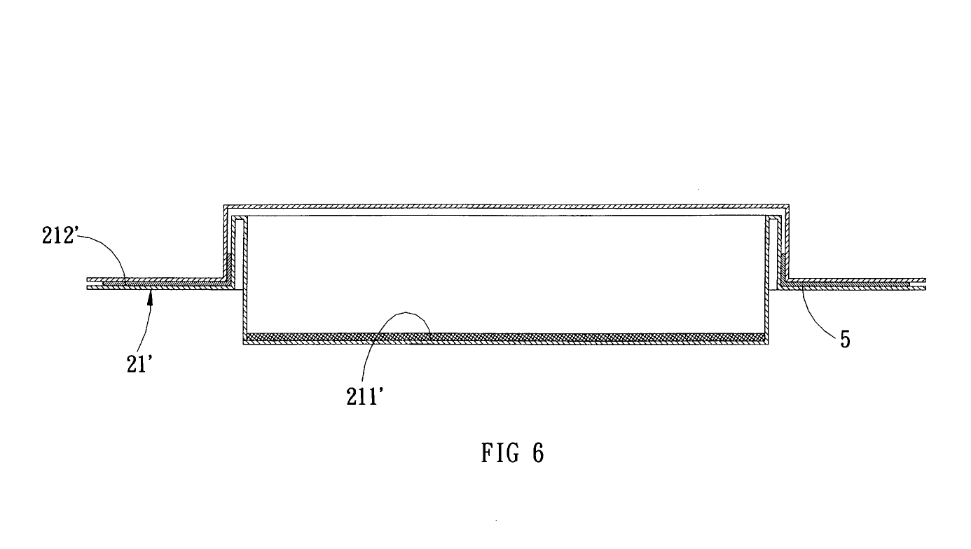

Further, the work zone 211 of the first shell member 21 can be disposed at an elevation different from the first joining part 212 other than at an elevation the same as the first joining part 212. That is, the work zone 211 can be disposed higher or lower than the first joining part 212 so that it is capable of adjusting space of the chamber 23. Referring to FIG. 6, a flat type heat pipe device in the second embodiment provides a work zone 211′ of the first shell member 21′ being lower than the first joining part 212′ for increasing the space of the chamber 23.

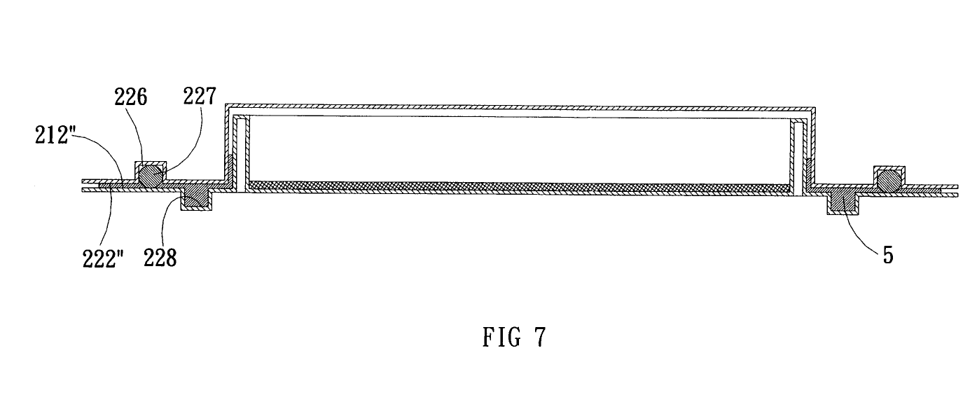

Besides, in case of the soldering paste providing large particles, it is necessary to prepare a large nozzle head (not shown) for coating the soldering paste. But, the large nozzle head easily results in excessive soldering paste entering the chamber 23. Referring to FIG. 7, the third embodiment of present invention provides a first joining part 212′ with a groove 228 extending along the periphery thereof for receiving large particles of the soldering paste or overflow soldering paste to prevent from entering the chamber 23. In addition, in order to increase tightness between the first joining part 212″ and the second joining part 222″, the second joining part 222″ in the instant embodiment has a groove 226 extending along the periphery thereof and a sealing ring 227 received in the recess 226. It is known by the skill persons of the art that the groove 228 can be arranged at the second joining part 222″ and the groove 226 can be arranged at the first joining part 212″ without restriction of the instant embodiment.

In view of above, it is appreciated that the flat type heat pipe and manufacturing process thereof and the packaging unit 2 according to the present invention provide an upright stop part 213 between the work zone 211, 211′ and the first joining part 212, 212′, 212″ to limit extent of the bonding member 5 while coating the bonding member 5 and to prevent the coated bonding member 5 from entering the chamber 23 and influencing properties and functions of the capillary device 3 and the work fluid 4 while pressingly fitting the first shell member 21 with the second shell member 22 for maintaining capability of heat dissipation of the flat type heat pipe. Further, the groove 228 at the first joining part 212″ is helpful for receiving large particles in the soldering paste and the excessively overflow soldering paste and the groove 226 at the second joining part 222″ and a seal ring 227 received in the groove 226 secure tightness between the first and second joining parts 212″, 222″ such that the flat type heat pipe device of the present invention provides advantage of the soldering paste being capable of melting without overflow.

While the invention has been described with referencing to preferred embodiments thereof, it is to be understood that modifications or variations may be easily made without departing from the spirit of this invention, which is defined by the appended claims.

What is claimed is:

1. A flat type heat pipe device, comprising:
a packaging unit; and
a bonding member; wherein the packaging unit further comprises:
a first shell member, having a work zone, a first joining part surrounding the work zone and an upright stop part disposed between the work zone and the joining part;
a second shell member, providing a shape corresponding to the first shell member, covering the first shell member, having a shell lid part spacing apart from the work zone and a second joining part disposed on the first joining part; and
the bonding member is disposed between the first joining part and the second joining part for adhering the first joining part to the second joining part.

2. The flat type heat pipe device as defined in claim 1, wherein the stop part has an elongated channel shaped cross section with an upright inner section, a top section and an upright outer section.

3. The flat type heat pipe device as defined in claim 1, wherein the first joining part and the second joining part are a horizontal wall respectively.

4. The flat type heat pipe device as defined in claim 1, wherein the shell lid part has a top side greater than the work zone and a vertical wall extending from periphery of the top side and being disposed outer side of the stop part.

5. The flat type heat pipe device as defined in claim 1, wherein the work zone is disposed at an elevation the same as the first joining part.

6. The flat type heat pipe device as defined in claim 1, wherein the work zone is disposed at an elevation different from the first joining part.

7. The flat type heat pipe device as defined in claim 1, wherein at least either the first joining part or the second joining part has a groove extending the periphery thereof.

8. The flat type heat pipe device as defined in claim 1, wherein at least either the first joining part or the second joining part has a groove extending the periphery thereof to receive a seal ring.

9. The flat type heat pipe device as defined in claim 1, wherein the first joining part has a first channel extending to the work zone from the periphery thereof and a filling pipe is received in the first channel with a closed end of the filling pipe being away from the work zone.

10. The flat type heat pipe device as defined in claim 9, wherein the second joining part has a second channel corresponding to the first channel for accommodating the filling pipe.

11. The flat type heat pipe device as defined in claim 1 further comprises a capillary device is disposed in a chamber defined by the work zone and the shell lid part.

12. The flat type heat pipe device as defined in claim 11 further comprises a work fluid disposed in the chamber.

13. The flat type heat pipe device as defined in claim 1, wherein the first shell member and the second shell member are made of aluminum or copper.

14. The flat type heat pipe device as defined in claim 1, wherein the bonding member is soldering wire, glue or adhesives.

15. The flat type heat pipe device as defined in claim 1, wherein the bonding paste is soldering paste.

16. A method for making a flat type heat pipe device, comprising following steps:
(A) providing a first shell member and a second shell member, which have a shape corresponding to each other, the first shell member having a work zone, a first joining part surrounding the work zone and an upright stop part disposed between the work zone and the first joining part, and the second shell member having a shell lid part corresponding to the work zone and a second joining part corresponding to the first joining part;
(B) coating a bonding member on at least one of the first and second joining parts; and
(C) covering the first shell member with the second shell member to allow the second shell member being attached to the first shell member.

17. The method for making a flat type heat pipe device as defined in claim 16, wherein the step (B) is to coat the bonding member to the first and second joining parts.

18. The method for making a flat type heat pipe device as defined in claim 16, wherein the step (B) forms a capillary device at the work zone.

19. The method for making a flat type heat pipe device as defined in claim 16, wherein the step (C) provides a fixture to clamp the joined first and second shell members for retaining the shell members in place.

20. The method for making a flat type heat pipe device as defined in claim 16, wherein the bonding member in step (A) is soldering paste and the joined shell members in the step (C) are heated up.

21. The method for making a flat type heat pipe device as defined in claim 20, wherein the joined shell members in step (C) is heated up with a high temperature stove.

22. The method for making a flat type heat pipe device as defined in claim 16, wherein a chamber is defined by the work zone and the shell lid part of the joined shell members, the first joining part provides a first groove channel extending to the work zone from the periphery thereof with a filling pipe being received in the first groove channel, the filling pipe has a length greater than the first groove channel with an end of the filling pipe communicating with the chamber and another end extending outward.

23. The method for making a flat type heat pipe device as defined in claim 22, further comprises following steps:
(D) providing a work fluid for being filled into the chamber through the filling pipe; and
(E) Closing the outward extending end of the filling pipe after gas being sucked out.

24. The method for making a flat type heat pipe device as defined in claim 22, further comprises following steps:
(D) admitting a work fluid to be filled in the chamber via the filling pipe after assurance of the first joining part being tightly attached to the second joining part; and
(E) Closing the outward extending end of the filling pipe after gas in the chamber being sucked out.

25. The method for making a flat type heat pipe device as defined in claim 23, wherein the outward end of the filling pipe in step (E) is closed after gas in the chamber being sucked out.

26. The method for making a flat type heat pipe device as defined in claim 23, wherein pressure in the chamber is reduced by means of the filling pipe before the gas being sucked out in step (E).

27. The method for making a flat type heat pipe device as defined in claim 24, wherein pressure in the chamber is reduced by means of the filling pipe before the gas being sucked out in step (E).

28. A packaging unit of a flat type heat pipe device, comprising:
a first shell member, having a work zone, a first joining part surrounding the work zone and an upright stop part disposed between the work zone and the joining part; and
a second shell member, providing a shape corresponding to the first shell member, covering the first shell member, having a shell lid part spacing apart from the work zone and a second joining part disposed on the first joining part.

29. The packaging unit of a flat type heat pipe device as defined in claim 28, wherein the stop part has an elongated channel shaped cross section with an upright inner section, a top section and an upright outer section.

30. The packaging unit of a flat type heat pipe device as defined in claim 28, wherein the first joining part and the second joining part are a horizontal wall respectively.

31. The packaging unit of a flat type heat pipe device as defined in claim 28, wherein the shell lid part has a top side greater than the work zone and a vertical wall extending from periphery of the top side and being disposed outer side of the stop part.

32. The packaging unit of a flat type heat pipe device as defined in claim 28, wherein the work zone is disposed at an elevation the same as the first joining part.

33. The packaging unit of a flat type heat pipe device as defined in claim 28, wherein the work zone is disposed at an elevation different from the first joining part.

34. The packaging unit of a flat type heat pipe device as defined in claim 28, wherein at least either the first joining part or the second joining part has a groove extending the periphery thereof.

35. The packaging unit of a flat type heat pipe device as defined in claim 28, wherein the first joining part has a first channel extending from the periphery thereof to the work zone and a filling pipe is received in the first channel with a closed end of the filling pipe being away from the work zone.

36. The packaging unit of a flat type heat pipe device as defined in claim 28, wherein the first shell member and the second shell member are made of aluminum or copper.

37. The packaging unit of a flat type heat pipe device as defined in claim 28, wherein the first joining part has a first channel extending from the periphery thereof to the work zone for accommodating a filling pipe.

38. The packaging unit of a flat type heat pipe device as defined in claim 37, wherein the second joining part has a second channel corresponding to the first channel for accommodating the filling pipe.

39. A method for packaging a flat type heat pipe device, comprising following steps:
(A) providing a first shell member and a second shell member, which have a shape corresponding to each other, the first shell member having a work zone, a first joining part surrounding the work zone and an upright stop part disposed between the work zone and the first joining part, and the second shell member having a shell lid part corresponding to the work zone and a second joining part corresponding to the first joining part;
(B) coating a bonding member on at least one of the first and second joining parts; and
(C) covering the first shell member with the second shell member to allow the second shell member being attached to the first shell member.

40. The method for packaging a flat type heat pipe device as defined in claim 39, wherein the step (B) is to coat the bonding member to the first and second joining parts.

41. The method for packaging a flat type heat pipe device as defined in claim 39, wherein the step (C) provides a fixture to clamp the joined first and second shell members for retaining the shell members in place.

42. The method for packaging a flat type heat pipe device as defined in claim 39, wherein the bonding member in step (A) is soldering paste and the joined shell members in the step (C) are heated up.

43. The method for packaging a flat type heat pipe device as defined in claim 42, wherein the joined shell members in step (C) is heated up with a high temperature stove.

44. The method for packaging a flat type heat pipe device as defined in claim 39, wherein a chamber is defined by the work zone and the shell lid part of the joined shell members, the first joining part provides a first groove channel extending to the work zone from the periphery thereof with a filling pipe being received in the first groove channel, the filling pipe has a length greater than the first groove channel with an end of the filling pipe communicating with the chamber and another end extending outward.
